(19) United States
(12) Patent Application Publication
(10) Pub. No.: US 2024/0241455 A1
(43) Pub. Date: Jul. 18, 2024

(54) ELECTRONIC DEVICE

(71) Applicant: InnoLux Corporation, Miao-Li County (TW)

(72) Inventors: Kuang-Ming FAN, Miao-Li County (TW); Ju-Li WANG, Miao-Li County (TW); Chun-Hung CHEN, Miao-Li County (TW)

(73) Assignee: InnoLux Corporation, Miao-Li County (TW)

(21) Appl. No.: 18/540,809

(22) Filed: Dec. 14, 2023

(30) Foreign Application Priority Data
Jan. 16, 2023 (CN) 202310067529.4

(51) Int. Cl. G03F 9/00; G03F 1/44; G03F 1/48; G03F 7/00

(52) U.S. Cl. CPC G03F 9/7076; G03F 1/44; G03F 1/48; G03F 7/70683; G03F 7/7085

(57) ABSTRACT

The electronic device of the present disclosure includes a redistribution structure, chip units, and a protective layer. The redistribution structure includes alignment marks. The chip units are electrically connected to the redistribution structure, and include a first chip unit and a second chip unit. The protective layer surrounds the first chip unit and the second chip unit. The chip units and the alignment marks are arranged along a direction. The first chip unit is disposed between the first alignment mark and the third alignment mark, and the second chip unit is disposed between the second alignment mark and the fourth alignment mark. The second alignment mark and the third alignment mark are disposed between the first chip unit and the second chip unit. The number of the alignment marks is greater than the number of the chip units.

### BACKGROUND OF THE DISCLOSURE

### 1. Field of the Disclosure

The present disclosure is related to an electronic device, in particular is directed to an electronic device with an alignment mark.

### 2. Description of the Prior Art

With the development of technology and demands for use, electronic devices are gradually becoming popular in daily life. In the manufacturing process, at least one set of alignment marks or at least one set of test keys are needed to facilitate the alignment or the detection when it is needed to integrate multiple chip units in an electronic device, so it would greatly affect the layout space of the electronic device and not be conducive for the improvement of the production yield.

### SUMMARY OF THE DISCLOSURE

In view of these, the present disclosure proposes a design-modified alignment mark to adjust the layout space of the electronic device or reduce the impact on the production yield. For example, the present disclosure proposes an alignment mark including a test key to have the function of measuring the die shift of chip units, so that the alignment mark of this disclosure becomes a versatile mark to reduce the layout space occupied by the alignment mark on the electronic device, to be conducive to the innovation of a packaging structure and the electronic device, and to improve the production yield of the electronic device.

In accordance with some examples, an electronic device which includes a redistribution structure, a plurality of chip units, and a protective layer is provided. The redistribution structure includes a plurality of alignment marks. The chip units are electrically connected to the redistribution structure, and include a first chip unit and a second chip unit. The protective layer surrounds the first chip unit and the second chip unit. The chip units and the alignment marks are arranged along a direction from a cross-sectional view. The alignment marks include a first alignment mark, a second alignment mark, a third alignment mark and a fourth alignment mark. The first chip unit is disposed between the first alignment mark and the third alignment mark, and the second chip unit is disposed between the second alignment mark and the fourth alignment mark. The second alignment mark and the third alignment mark are disposed between the first chip unit and the second chip unit. A number of the alignment marks is greater than a number of the chip units.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 illustrates a schematic top view of an electronic device according to a first example of the present disclosure.

FIG. 2 illustrates a schematic top view of a variant embodiment according to the first example of the present disclosure.

The upper part of FIG. 3 illustrates a schematic top view of a variant example of one of the alignment marks of the electronic device according to the first example of the present disclosure.

The lower part of FIG. 3 illustrates a schematic side view of a variant example of one of the alignment marks of the electronic device according to the first example of the present disclosure.

FIG. 4 illustrates a schematic diagram of an exploded top view of a plurality of mark units corresponding to the alignment mark shown in FIG. 3.

The upper part of FIG. 5 illustrates a schematic top view of another variant example of one of the alignment marks of the electronic device according to the first example of the present disclosure.

The lower part of FIG. 5 illustrates a schematic cross-sectional view along the B-B′ line of another variant example of one of the alignment marks of the electronic device according to the first example of the present disclosure.

FIG. 6 illustrates a schematic diagram of an exploded top view of a plurality of mark units corresponding to the alignment mark shown in FIG. 5.

The upper part of FIG. 7 illustrates a schematic top view of another variant example of one of the alignment marks of the electronic device according to the first example of the present disclosure.

The lower part of FIG. 7 illustrates a schematic cross-sectional view along the line C-C′ of another variant example of one of the alignment marks of the electronic device according to the first example of the present disclosure.

FIG. 8 illustrates a schematic diagram of an exploded top view of a plurality of mark units corresponding to the alignment mark shown in FIG. 7.

FIG. 9 illustrates a schematic top view of one of the alignment marks of the electronic device 101 according to the first example of the present disclosure for use as a test key.

FIG. 10 illustrates a schematic cross-sectional view of an electronic device according to the second example of the present disclosure along the line A-A′ in FIG. 1.

FIG. 10A illustrates a schematic cross-sectional view of the electronic device according to the third example of the present disclosure along the line A-A′ in FIG. 1.

FIG. 10B illustrates a schematic partial enlarged view of a partial region of the electronic device in FIG. 10A.

FIG. 11 illustrates a schematic cross-sectional view of an electronic device according to a fourth example of the present disclosure along the line A-A′ in FIG. 1.

FIG. 12 illustrates a schematic cross-sectional view of an electronic device according to a fifth example of the present disclosure along the line A-A′ in FIG. 1.

FIG. 13 illustrates a variant embodiment of the electronic device according to the sixth embodiment of the present disclosure corresponding to FIG. 12.

FIG. 14 illustrates a schematic cross-sectional view of an electronic device 7 according to a seventh embodiment of the present disclosure along the line A-A′ in FIG. 1.

FIG. 15 illustrates a schematic cross-sectional view of an electronic device according to an eighth example of the present disclosure along the line A-A′ in FIG. 1.

### DETAILED DESCRIPTION

The present disclosure may be understood by reference to the following detailed description, taken in conjunction with the drawings as described below. For purposes of illustrative clarity understood, various drawings of this disclosure show a portion of the electronic device, and certain elements in various drawings may not be drawn to scale. In addition, the number and dimension of each device shown in drawings are only illustrative and are not intended to limit the scope of the present disclosure.

Certain terms are used throughout the description and following claims to refer to particular components. As one skilled in the art will understand, electronic equipment manufacturers may refer to a component by different names. This document does not intend to distinguish between components that differ in name but not in function.

In the following description and in the claims, the terms “include”, “comprise” and “have” are used in an open-ended fashion, and thus should be interpreted to mean “include, but not limited to . . . ”.

It will be understood that when an element or layer is referred to as being “on another component or on another layer” or “electrically connected to another component or electrically to another layer”, it may be directly on or directly electrically connected to the other element or layer, or intervening elements or layers may be presented. In contrast, when an element is referred to as being “directly on” or “directly electrically connected to” another element or layer, there are no intervening elements or layers presented.

Although terms such as first, second, third, etc., may be used to describe diverse constituent elements, such constituent elements are not limited by the terms. The terms are used only to discriminate a constituent element from other constituent elements in the specification.

It should be noted that the technical features in different embodiments described in the following may be replaced, recombined, or mixed with one another to constitute another embodiment without departing from the spirit of the present disclosure.

Although terms such as first, second, third, etc. may be used to describe various constituent elements, such constituent elements are not limited by these terms. These terms are only used to distinguish one constituent element from another constituent element in the specification. The claims may not use the same terms, but may use the terms first, second, third etc. with respect to the order of claimed elements. Therefore, in the following description, in the claims, a first constituent element may be a second constituent element.

In the present disclosure, various electronic devices may include for example an electronic component, a semiconductor device, a packaging device, a display device, a light-emitting device including a backlight module, a solar cell, a sensing device, a vehicle device, an antenna device, a splicing device, or a high-frequency device, but the present disclosure is not limited thereto. The electronic device may include a flexible electronic device or a bendable electronic device. The display device may be a non-self-illuminating display device or a self-illuminating display device, to include such as a light-emitting diode (LED), liquid crystal, fluorescence, phosphor or other suitable materials, and the materials may be optionally combined, but the present disclosure is not limited thereto. The splicing device may be, for example, a display splicing device or an antenna splicing device, but the present disclosure is not limited thereto. The antenna device may be a liquid crystal antenna device or a non-liquid crystal antenna device. The sensing device may be a sensing device for sensing capacitance, light, heat or ultrasonic waves, but the present disclosure is not limited thereto. In the present disclosure, an electronic element may include a passive elements or an active element, such as a capacitor, a resistor, an inductor, a diode, a transistor. The diode may include a light-emitting diode or a photodiode. The light-emitting diode may for example, include an organic light-emitting diode (OLED), a sub-millimeter light-emitting diode (mini LED), a micro light-emitting diode (micro LED), or a quantum dot light-emitting diode, but the present disclosure is not limited thereto. It should be noted that, the electronic device of the present disclosure may be any combination of the above, but the present disclosure is not limited thereto. Hereinafter, the display device is used as an electronic device to describe the present disclosure, but the present disclosure is not limited thereto.

In present disclosure, the measurement methods of length, thickness, width, height, distance and area may be obtained by an optical microscope (OM), an electron microscope (such as a scanning electron microscope, SEM) or other methods, but the present disclosure is not limited thereto.

In some embodiments of the present disclosure, the first direction D1 may be the X direction and the second direction D2 may be the Y direction. In other embodiments of the present disclosure, the first direction D1 may be the Y direction and the second direction D2 may be the X direction. The third direction is the Z direction, which may be the normal direction of the electronic device or the top view direction of the electronic device, the Z direction is perpendicular to the X direction and the Z direction is perpendicular to the Y direction.

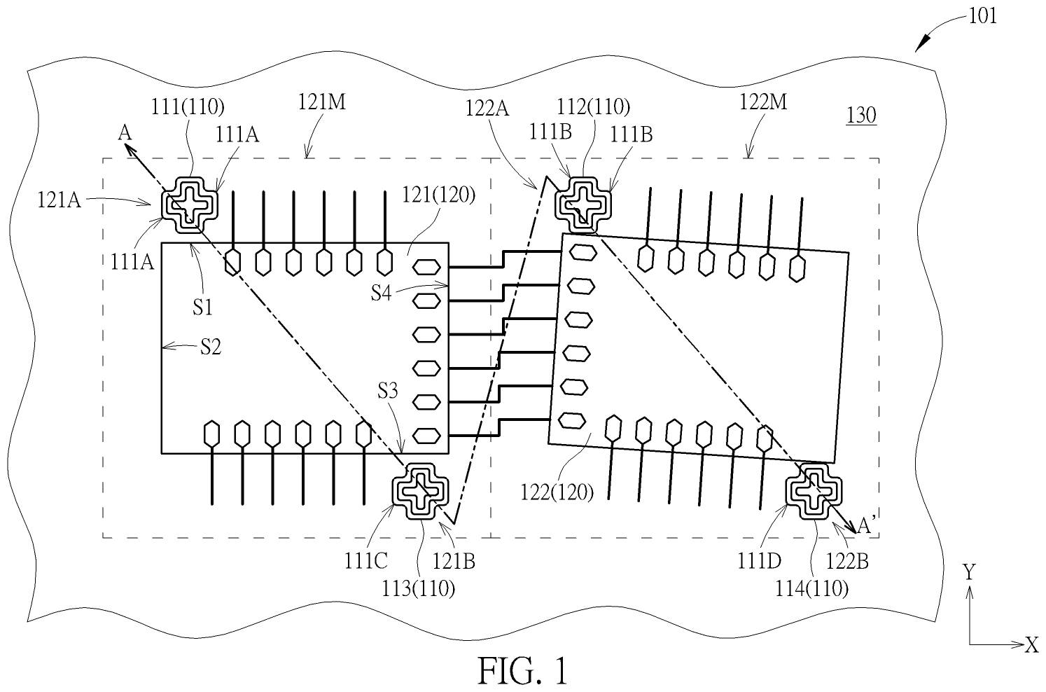

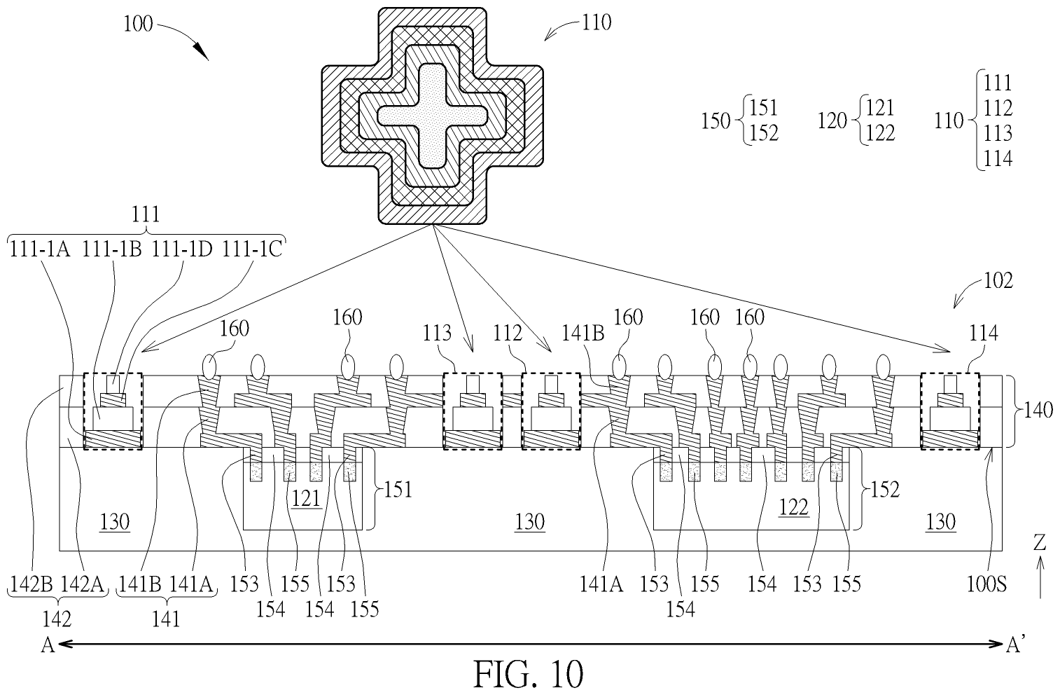

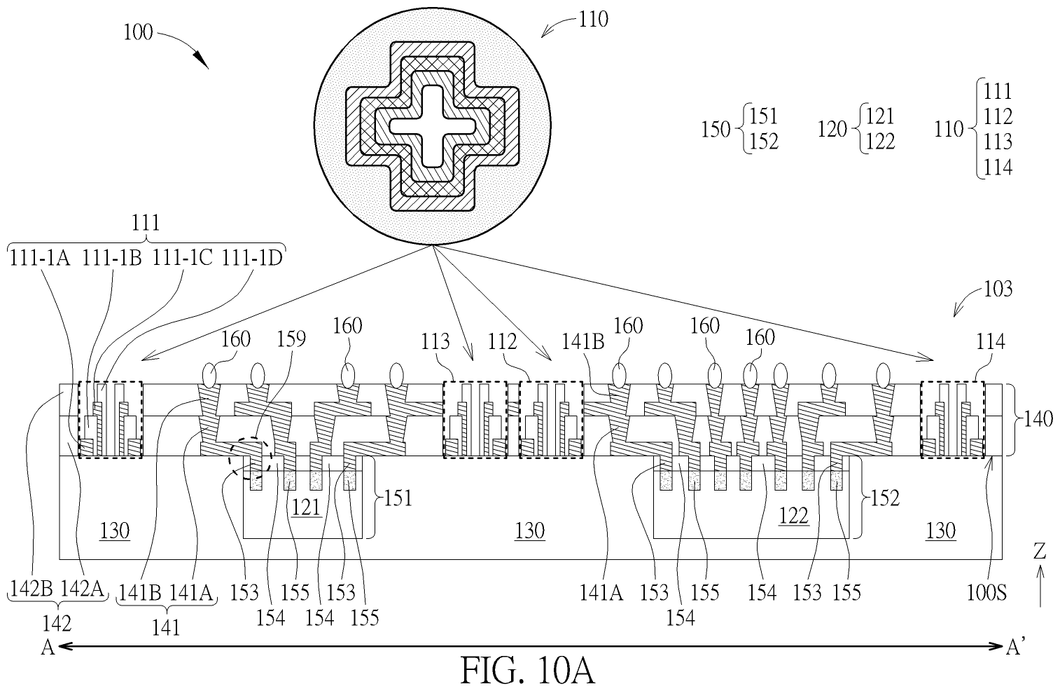

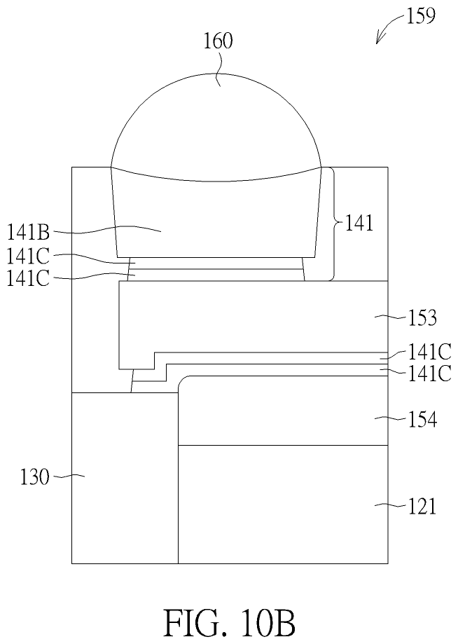

FIG. 1 illustrates a schematic top view of an electronic device 101 according to a first example of the present disclosure. Please refer to FIG. 1 and to FIG. 10 at the same time. The electronic device 101 may include a plurality of alignment marks 110 in the redistribution structure 140, a plurality of chip units 120, and a protective layer 130. The alignment marks 110 may at least include a first alignment mark 111 and a second alignment mark 112, but the present disclosure is not limited thereto. The chip units 120 are electrically connected to the redistribution structure 140, and the chip units 120 may at least include a first chip unit 121 and a second chip unit 122 which are surrounded by the protective layer 130, but the present disclosure is not limited thereto.

In some examples of the present disclosure, the first alignment mark 111 may be provided to correspond to the first chip unit 121, and in some examples of the present disclosure, the second alignment mark 112 may be provided to correspond to the second chip unit 122. “Provided to correspond to” may mean, for example, that a given element may be arranged adjacent to a reference element, for example in a marginal region of the reference element, but the given element may or may not directly contact the reference element. For example, in some embodiments of the present disclosure, the first alignment mark 111 may be provided in the first position 121A in a marginal region 121M adjacent to the first chip unit 121 of the electronic device 101, so that the first alignment mark 111 may be disposed in the marginal region 121M adjacent to the first chip unit 121 and adjacent to the first chip unit 121. On the other hand, the second alignment mark 112 may be provided in the first position 122A in a marginal region 122M adjacent to the second chip unit 122 of the electronic device 101, so that the second alignment mark 112 may be disposed in the marginal region 122M adjacent to the second chip unit 122 and adjacent to the second chip unit 122, but the present disclosure is not limited thereto.

In some examples of the present disclosure, the alignment marks 110 may further include a third alignment mark 113 and a fourth alignment mark 114, for example, the third alignment mark 113 is provided to correspond to the first chip unit 121, and the four alignment mark 114 is provided to correspond to the second chip unit 122. In some embodiments of the present disclosure, the third alignment mark 113 may be disposed in the second position 121B of the marginal region 121M adjacent to the first chip unit 121 and adjacent to the first chip unit 121. On the other hand, the fourth alignment mark 114 may be disposed in the second position 122B of the marginal region 122M adjacent to the second chip unit 122 and adjacent to the second chip unit 122, but the present disclosure is not limited thereto. In some embodiments of the present disclosure, the first position 121A and the second position 121B may be respectively located on two adjacent sides of the marginal region 121M, or in other embodiments of the present disclosure, the first position 121A and the second position 121B may be respectively located on two opposite sides of the marginal region 121M, but the present disclosure is not limited thereto. Similarly, in some embodiments of the present disclosure, the first position 122A and the second position 122B may be respectively located on two adjacent sides of the marginal region 122M, or in other embodiments of the present disclosure, the first position 122A and the second position 122B may be respectively located on two opposite sides of the marginal region 122M, but the present disclosure is not limited thereto. FIG. 1 shows an example in which the first position 121A and the second position 121B are respectively located on two opposite sides of the marginal region 121M, and the first position 122A and the second position 122B are respectively located on two opposite sides of the marginal region 122M, but the present disclosure is not limited thereto.

Further, the first chip unit 121 may include four sides, wherein the first side S1 is substantially parallel to the third side S3, the second side S2 is substantially parallel to the fourth side S4, and the first side S1 is substantially perpendicular to the second side S2. The first alignment mark 111 may be arranged adjacent to the first side S1, the third alignment mark 113 may be arranged adjacent to the third side S3, and the first alignment mark 111 and the third alignment marks 113 do not overlap along an extension direction of the second side S2. Preferably, the first alignment mark 111 may be arranged in the marginal region 121M adjacent to the first side S1, and arranged in the marginal region 121M adjacent to the corner where the first side S1 and the second side S2 meet. Preferably, the third alignment mark 113 may be arranged in the marginal region 121M adjacent to the third side S3 and arranged in the marginal region 121M adjacent to the corner where the third side S3 and the fourth side S4 meet. The arrangement of the second chip unit 122 may also refer to the above principles to correspondingly arrange the second alignment mark 112 and the fourth alignment mark 114 in the marginal region 122M adjacent to the four sides thereof, so the details are not elaborated here. The marginal region referred to in the present disclosure may be, for example, from a top view direction, the regions of the electronic device other than the regions where the chip unit is located and the wiring layout electrically connected to the chip unit is located.

According to some examples of the present disclosure, the number of the alignment marks in the electronic device of each example may be greater than the number of the chip units. The example of FIG. 1 shows four alignment marks, such as the first alignment mark 111, the second alignment mark 112, the third alignment mark 113 and the fourth alignment mark 114, corresponding to two chip units, such as the first chip unit 121 and the second chip unit 122, but the present disclosure is not limited thereto.

In some examples of the present disclosure, at least one of the alignment marks, such as the first alignment mark 111, the second alignment mark 112, the third alignment mark 113 or the fourth alignment mark 114, may include at least one rounded corner. FIG. 1 shows that the first alignment mark 111 includes a rounded corner 111C, the second alignment mark 112 includes a rounded corner 112C, the third alignment mark 113 includes a rounded corner 113C, and the fourth alignment mark 114 includes a rounded corner 114C, but the present disclosure is not limited thereto. For example, an alignment mark with the design of a rounded corner may reduce the risk of film cracking.

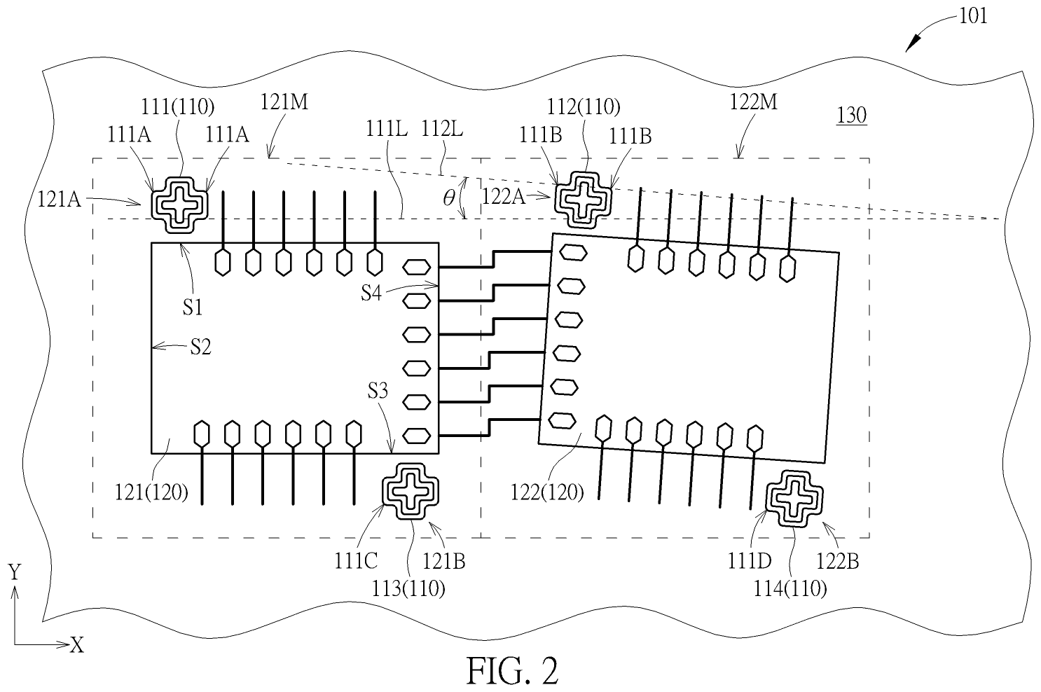

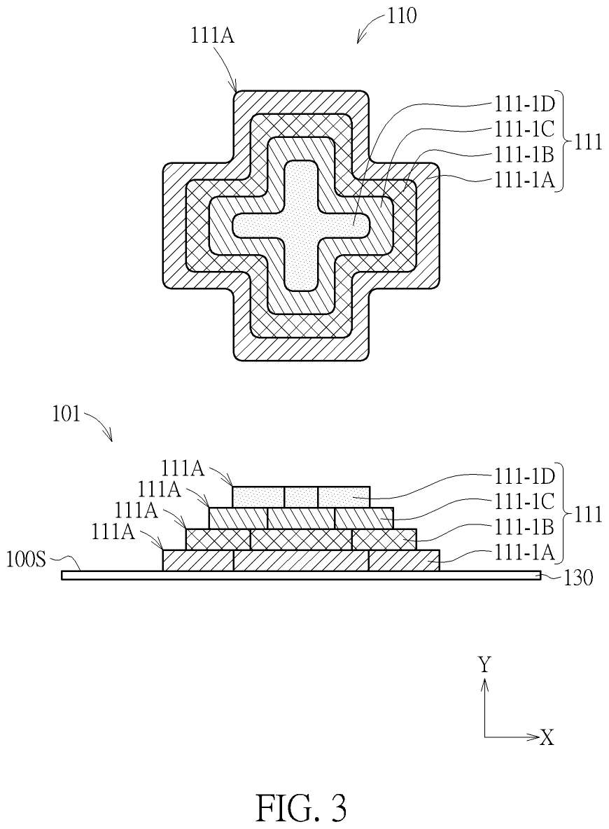

FIG. 2 illustrates a schematic top view of a variant example according to the first example of the present disclosure. In some embodiments of the present disclosure, the first alignment mark 111 may have an extension line 111L extending from a certain straight line in its pattern (for example, a straight line formed by the outer edge of the pattern). Similarly, the second alignment mark 112 may have another extension line 112L extending from a certain straight line in its pattern (for example, a straight line formed by the outer edge of the pattern). According to some examples of the present disclosure, there may be an included angle θ between the extension line 111L of the first alignment mark 111 and the extension line 112L of the second alignment mark 112. According to some other examples of the present disclosure, the included angle θ may have an appropriate range, for example, the included angle θ may be greater than or equal to 0 degree, or the included angle θ maybe less than or equal to 15 degrees, such that 0°≤θ≤15°. In some embodiments of the present disclosure, from a schematic top view, the extension direction of the connecting lines of the edges of the alignment marks may represent the first alignment mark 111 and the second alignment mark 112 arranged parallel to each other when the included angle θ is equal to 0 degree, and the first chip unit 121 and the second chip unit 122 may be arranged parallel to each other or non-parallel to each other (as shown in FIG. 1). In some embodiments of the present disclosure, the first alignment mark 111 and the second alignment mark 112 are not parallel to each other, and the first chip unit 121 and the second chip unit 122 may not be arranged parallel to each other when the included angle θ is not equal to 0 degree. From the top view direction of the electronic device of the present disclosure, the inspection module may be, for example, an automated optical inspection (AOI) to measure the offset of the chip units in the X direction or the Y direction and to give feedback to the next process for compensation, but it is not limited thereto. In some embodiments, the inspection module may include a white light source (for example, providing light with a wavelength ranging from 360 nm to 700 nm), a camera, and a spectrometer, but it is not limited thereto.

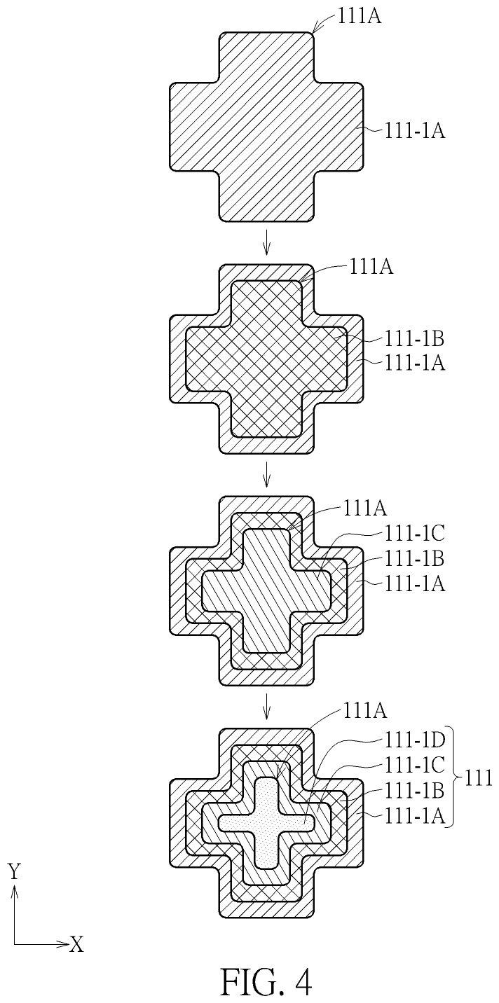

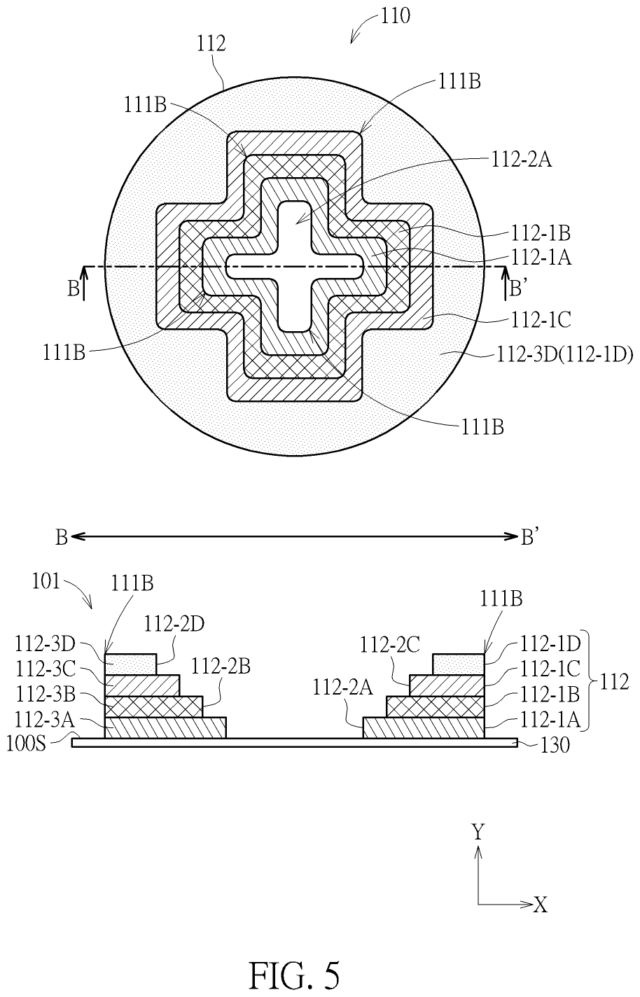

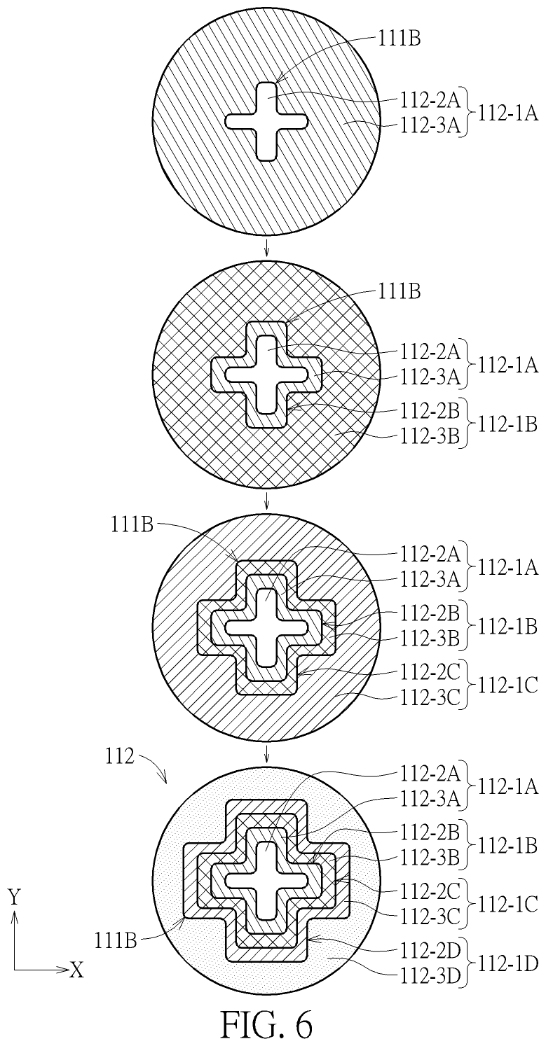

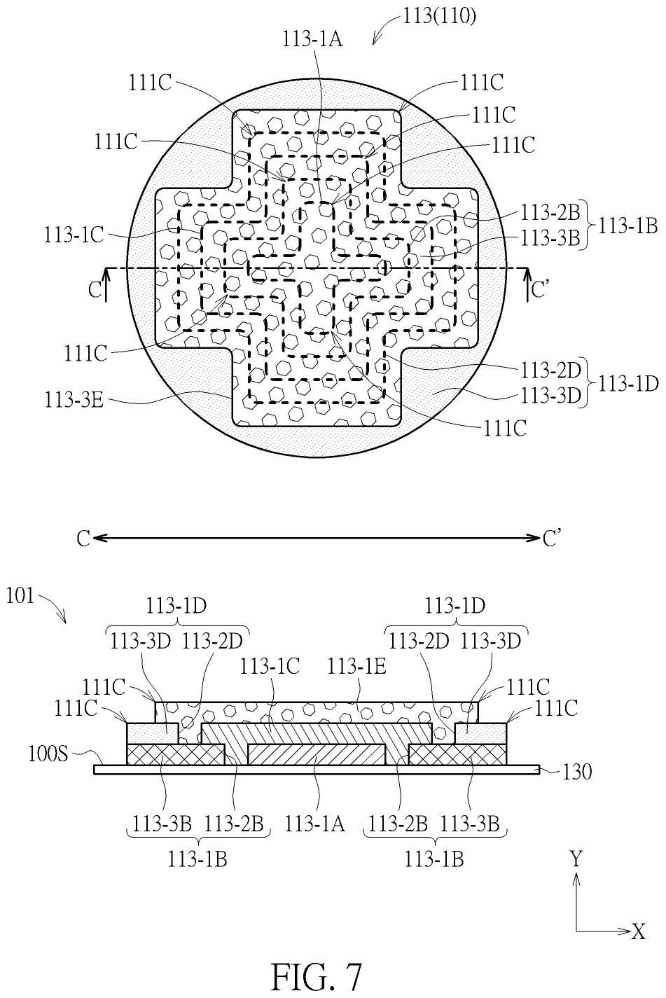

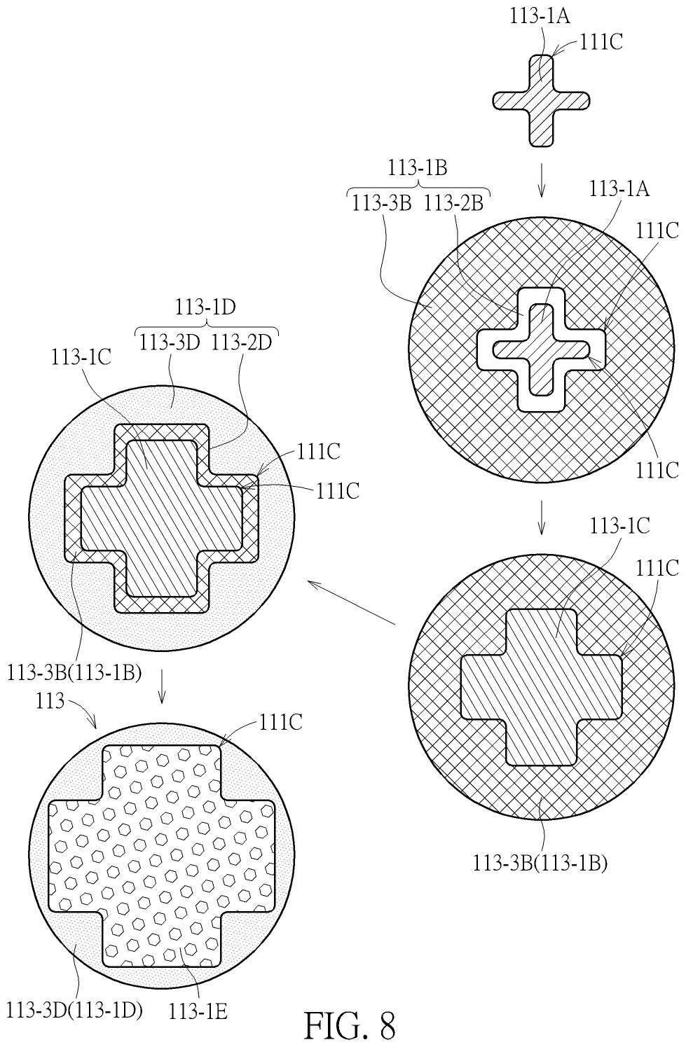

The upper part of FIG. 3 illustrates a schematic top view of a variant example of one of the alignment marks 110 of the electronic device 101 according to the first example of the present disclosure. The lower part of FIG. 3 illustrates a schematic side view of a variant example of one of the alignment marks 110 of the electronic device 101 according to the first example of the present disclosure. FIG. 4 illustrates a schematic diagram of an exploded top view of a plurality of mark units corresponding to the alignment mark shown in FIG. 3. The upper part of FIG. 5 illustrates a schematic top view of another variant example of one of the alignment marks 110 of the electronic device 101 according to the first example of the present disclosure. The lower part of FIG. 5 illustrates a schematic cross-sectional view along the B-B′ line of another variant example of one of the alignment marks 110 of the electronic device 101 according to the first example of the present disclosure. FIG. 6 is a schematic diagram of an exploded top view of a plurality of mark units corresponding to the alignment mark shown in FIG. 5. The upper part of FIG. 7 illustrates a schematic top view of another variant example of one of the alignment marks 110 of the electronic device 101 according to the first example of the present disclosure. The lower part of FIG. 7 illustrates a schematic cross-sectional view along the line C-C′ of another variant example of one of the alignment marks 110 of the electronic device 101 according to the first example of the present disclosure. FIG. 8 illustrates a schematic diagram of an exploded top view of a plurality of mark units corresponding to the alignment mark shown in FIG. 7.

One of the alignment marks 110 of the electronic device 101 of the present disclosure, such as the first alignment mark 111, the second alignment mark 112, the third alignment mark 113 or the fourth alignment mark 114, may include one of an island-like mark, a window-like mark and a hybrid mark. As shown in FIG. 3, one of the alignment marks 110 of the electronic device 101 according to the first example of the present disclosure may be an example of an island-like mark. The island-like mark may refer to an example in which each one of a plurality of mark units in the alignment mark may be a solid mark or have a solid pattern, and they are stacked upwards from a larger one to a smaller one to form a tower-like appearance. Please refer to FIG. 3 and FIG. 4 at the same time. Taking the first alignment mark 111 as an example, it may include a mark unit 111-1A, a mark unit 111-1B, a mark unit 111-1C and a mark unit 111-1D, but the present disclosure is not limited thereto. On the one hand, the mark unit 111-1A may be the one of the largest size, the mark unit 111-1B may be a mark unit slightly smaller than the mark unit 111-1A in shape, the mark unit 111-1C may be a mark unit slightly smaller than the mark unit 111-1B in shape and the mark unit 111-1D may be a mark unit slightly smaller than the mark unit 111-1C in shape. On the other hand, the first alignment mark 111 may be directly disposed on the surface of a film layer of the electronic device 101, for example, the electronic device 101 includes a protective layer 130 which has a surface 100S, and the mark unit 111-1A may be disposed on the surface 100S and directly contacts the protective layer 130, the mark unit 111-1B may be directly disposed on the surface of the mark unit 111-1A, the mark unit 111-1C may be directly disposed on the surface of the mark unit 111-1A, and the mark unit 111-1D may be directly disposed on the surface of the mark unit 111-1A. Therefore, the mark unit 111-1A, the mark unit 111-1B, the mark unit 111-1C and the mark unit 111-1D may be sequentially formed, so that they are sequentially and correspondingly stacked from a larger one to a smaller one in a direction away from the surface 100S of the electronic device 101 to form the tower-shaped first alignment mark 111 when making the first alignment mark 111. FIG. 3 and FIG. 4 illustrate an embodiment in which the multiple mark units in the first alignment mark 111 are cross-shaped, and the multiple mark units may also be triangular, star-shaped, rectangular or any other suitable shape, but the present disclosure is not limited thereto. In addition, one or more of the mark unit 111-1A, the mark unit 111-1B, the mark unit 111-1C and the mark unit 111-D may also have a rounded corner 111C.

As shown in FIG. 5, one of the alignment marks 110 of the electronic device 101 according to the first example of the present disclosure may be an example of a window-like mark. The window-like mark may mean that each one of the mark units in an alignment mark may be a window-like mark including a hollow pattern in a solid outer frame, and the hollow patterns are stacked upwards from a smaller one to a larger one to become a mark which has an opening size which gradually increases upwards. Please refer to FIG. 5 and FIG. 6 at the same time. In some embodiments of the present disclosure, taking the second alignment mark 112 as an example, it may include, for example, a mark unit 112-1A, a mark unit 112-1B, a mark unit 112-1C and a mark unit 112-1D, but the present disclosure is not limited thereto. On one hand, the mark unit 112-1A may be a mark unit in which the hollow pattern 112-2A has the smallest size, and the mark unit 112-1B may be a mark unit in which the hollow pattern 112-2B is slightly larger than the hollow pattern 112-2A of the mark unit 112-1A in shape, the mark unit 112-1C may be a mark unit in which the hollow pattern 112-2C is slightly larger than the hollow pattern 112-2B of the mark unit 112-1B in shape, and the mark unit 112-1D may be a mark unit in which the hollow pattern 112-1D is slightly larger than the hollow pattern 112-2C of the mark unit 112-1C in shape, but the solid outer frame 112-3A of the mark unit 112-1A, the solid outer frame 112-3B of the mark unit 112-1B, the solid outer frame 112-3C of the mark unit 112-1C and the solid outer frame 112-3D of the mark unit 112-1D may have the same shape or the same outer dimension. FIG. 5 and FIG. 6 show an example in which the solid outer frame of each mark unit is circular in shape. The shape of the solid outer frame may also be ellipse, rectangle, square or any other suitable shape, but the present disclosure is not limited thereto.

On the other hand, the second alignment mark 112 may be disposed on the surface of a film layer of the electronic device 101. For example, the electronic device 101 includes a protective layer 130 with a surface 100S, and the mark unit 112-1A may be directly disposed on the surface 100S and in direct contact with the protective layer 130, the mark unit 112-1B may be directly disposed on the surface of the mark unit 112-1A, the mark unit 112-1C may be directly disposed on the surface of the mark unit 112-1B, and the mark unit 112-1D may be directly disposed on the surface of the mark unit 112-1C so that the hollow pattern 112-2A of the mark unit 112-1A, the hollow pattern 112-2B of the mark unit 112-1B, the hollow pattern 112-2C of the mark unit 112-1C and the hollow patterns 112-2D of the mark unit 112-1D are correspondingly stacked from a smaller one to a larger one sequentially in a direction away from the surface 100S of the electronic device 101 to form a tower-like alignment mark with an increasing opening. FIG. 5 and FIG. 6 show an embodiment in which the hollow patterns of the mark units in the second alignment mark 112 are in a shape of a cross, however, the hollow patterns may also be triangular, star-shaped, rectangular or any other suitable shape, but the present disclosure is not limited thereto.

As shown in FIG. 7, one of the alignment marks 110 of the electronic device 101 according to the first example of the present disclosure may be an example of a hybrid mark. A hybrid mark may refer to that the mark units in an alignment mark may have the solid mark of an island-like mark in the hollow pattern of a window-like mark, and the solid marks or hollow patterns are stacked upwards from a smaller one to a larger one in order to form a complement mark. Please refer to FIG. 7 and FIG. 8 at the same time. In some embodiments of the present disclosure, taking the third alignment mark 113 as an example, it may include, for example, a mark unit 113-1A, a mark unit 113-1B, a mark unit 113-1C, a mark unit 113-1D and mark unit 113-1E, but the present disclosure is not limited thereto. On one hand, the mark unit 113-1A may be the mark unit of the smallest size, the mark unit 113-1B may be a mark unit in which the hollow pattern 113-2B is slightly larger than the mark unit 113-1A in shape, the mark unit 113-1C may be a mark unit slightly larger than the mark unit 113-1A and the hollow pattern 113-2B of the mark unit 113-1B in shape, and the mark unit 113-1D may be a mark unit in which the hollow pattern 113-2D is slightly larger than the mark unit 113-1C, and the mark unit 113-1E may be a mark unit slightly larger than the mark unit 113-1C and the hollow pattern 113-2D of the mark unit 113-1D in shape. However, the shapes or the outer dimensions of the solid outer frame 112-3B of the mark unit 112-1B and the solid outer frame 112-3D of the mark unit 112-1D may be the same. FIG. 7 and FIG. 8 show an example in which the solid outer frames of each mark unit are circular in shape. The shapes of the solid outer frames may also be ellipse, rectangle, square or any other suitable shape, but the present disclosure is not limited thereto.

On the other hand, the mark unit 113-1A and the mark unit 113-1B may be directly disposed on the surface 100S of the protective layer 130 of the electronic device 101 or in direct contact with the protective layer 130, the mark unit 113-1B may be directly disposed on the surface 100S of the electronic device 101 or in direct contact with the protective layer 130, the mark unit 113-1C may be directly disposed on the surface of the mark unit 113-1A, the mark unit 113-1D may be directly disposed on the surface of the mark unit 113-1B, and the mark unit 113-1E may be directly disposed on the surface of the mark unit 113-1C, so that the mark unit 113-1A, the hollow pattern 113-2B of the mark unit 113-1B, the mark unit 113-1C, the hollow pattern 113-2D of the mark unit 113-1D, and the mark unit 113-1E are correspondingly stacked in a direction away from the surface 100S of the electronic device 101 from a smaller one to a larger one to form a hybrid alignment mark according to the island-like mark group or to the window-like mark group to which they belong. FIG. 7 and FIG. 8 show an embodiment in which the hollow patterns of the mark units in the third alignment mark 113 are in a shape of a cross, however, the hollow patterns may also be triangular, star-shaped, rectangular or any other suitable shape, but the present disclosure is not limited thereto.

According to some examples of the present disclosure, at least one of the alignment marks may include three mark units, or further include more than three mark units. In other embodiments of the present disclosure, an insulating material may be for use in the island-like mark in the mark units of an alignment mark if one of the alignment marks is an island-like mark or a window-like mark or a hybrid mark. For example, the insulating material may include a transparent material or a translucent material, such as a transparent photoresist or photosensitive polyimide (PSPI), but the present disclosure is not limited thereto. A hybrid mark may have the advantages of a lower vertical height or fewer stacked layers. For example, two mark units may form a single-layer alignment mark, four mark units may form a two-layer alignment mark, six mark units may form a three-layer alignment mark, and so on. In other words, n mark units may form an alignment mark with n/2 layers when n is an even number.

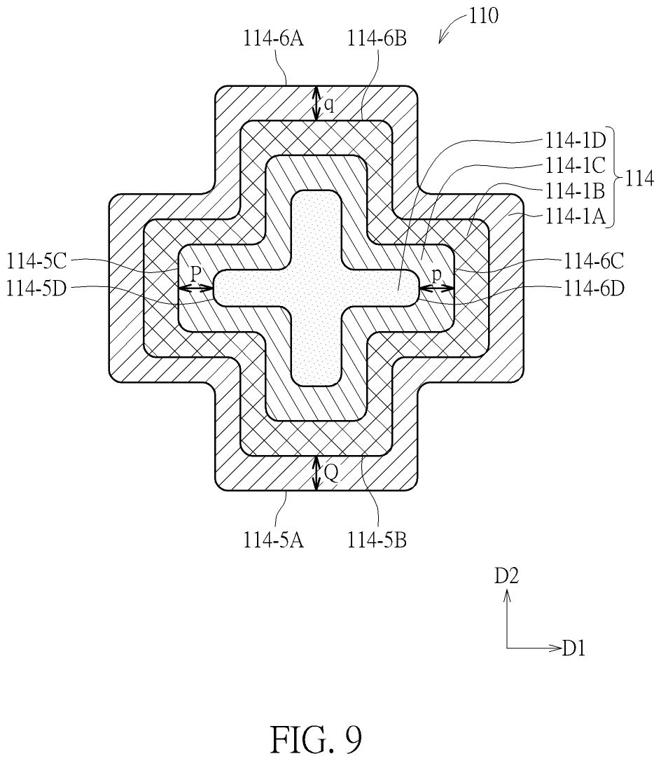

FIG. 9 illustrates a schematic top view of one of the alignment marks 110 of the electronic device 101 according to the first example of the present disclosure for use as a test key. In addition to the alignment function, at least one of the alignment marks in the electronic device 101 of the present disclosure may also include the function of a test key for measuring the alignment deviation value. Please refer to FIG. 9. In some embodiments of the present disclosure, taking the fourth alignment mark 114 as an example, the fourth alignment mark 114 may include a plurality of mark units for use as a test key, such as a mark unit 114-1A, a mark unit 114-1B, a mark unit 114-1C and a mark unit 114-1D, but the present disclosure is not limited thereto. On one hand, the test key of the outer mark unit may represent the front-layer key relative to the inner mark unit. On the other hand, the test key of the inner mark unit may represent the current-layer key relative to the outer mark unit. In other words, the test key includes a front-layer key and a current-layer key. Please refer to FIG. 9, the mark unit 114-1A represents the front layer of the mark unit 114-1B relative to the mark unit 114-1B, and the mark unit 114-1B represents the current layer relative to the mark unit 114-1A, the mark unit 114-1B represents the front layer of the mark unit 114-1C relative to the mark unit 114-1C, and the mark unit 114-1C represents the current layer relative to the mark unit 114-1B, and so on.

Taking the mark unit 114-1C and the mark unit 114-1D as an example, on one hand, the mark unit 114-1D has a first outer edge 114-5D and a second outer edge 114-6D along a direction perpendicular to the first direction D1, and the mark unit 114-1C has a first outer edge 114-5C perpendicular to the first direction D1 and closest to the first outer edge 114-5D, and a second outer edge 114-6C perpendicular to the first direction D1 and closest to the second outer edge 114-6D. On the other hand, the mark unit 114-1B has a first outer edge 114-5B and a second outer edge 114-6B perpendicular to the second direction D2, and the mark unit 114-1A has a first outer edge 114-5A perpendicular to the second direction D2 and closest to the first outer edge 114-5B, and a second outer edge 114-6A perpendicular to the second direction D2 and closest to the second outer edge 114-6B. The first direction D1 and the second direction D2 may be respectively parallel to the surface 100S of the electronic device 101. The first direction D1 and the second direction D2 may be perpendicular to each other.

According to some examples of the present disclosure, there may be a gap between the adjacent outer edge of the current layer and the outer edge of the front layer, and the gap may have a gap value. The gap between the adjacent outer edge of the current layer and the outer edge of the front layer may be used to measure the misalignment between the adjacent current layer and the front layer. For example, please refer to the illustration of FIG. 9, there may be a gap between the first outer edge 114-5C and the first outer edge 114-5D, and the gap may have a gap value P to represent a gap distance, and there may be a gap between the first outer edge 114-5A and the first outer edge 114-5B, and the gap may have a gap value Q to represent another gap distance. Or, there may be a gap between the second outer edge 114-6C and the second outer edge 114-6D, and the gap may have a gap value p to represent another gap distance, and at the same time, there may be a gap between the second outer edge 114-6A and the second outer edge 114-6B, and the gap may have a gap value q to represent another gap distance.

In some embodiments of the present disclosure, the gap value P and the gap value p along the first direction D1 may represent an misalignment between the adjacent current layer mark unit 114-1C and the front layer mark unit 114-1D along the first direction D1 (i.e., the X direction) if the first direction D1 is the X direction. In other examples of the present disclosure, the gap value P and the gap value p along the first direction D1 between the front-layer key and the current-layer key may measure an misalignment between the adjacent current layer mark unit 114-1C and the front layer mark unit 114-1D along the first direction D1 (i.e., the Y direction) if the first direction D1 is the Y direction. When the first direction D1 and the second direction D2 are perpendicular to each other, the gap value P and the gap value p may measure an misalignment between the adjacent current layer mark unit 114-1C and the front layer mark unit 114-1D along the first direction D1. The gap value Q and the gap value q between the current-layer key and front-layer key along the second direction D2 between the adjacent current layer mark unit 114-1A and the front layer mark unit 114-1B may measure an misalignment along the second direction D2. At this time, the first direction D1 may be either one of the X direction and the Y direction, and the second direction D2 may be the other one of the X direction and the Y direction. FIG. 9 shows that the gap value P and the gap value p may represent the misalignment along the X direction between the adjacent current layer mark unit 114-1C and the front layer mark unit 114-1D, and the gap value Q and the gap value q may represent the misalignment along the Y direction between the adjacent current layer mark unit 114-1A and the front layer mark unit 114-1B, but the present disclosure is not limited thereto.

According to some examples of the present disclosure, the gap value along one direction between the adjacent current layer mark unit and front layer mark unit may be used to calculate the alignment deviation value between the adjacent current layer mark unit and front layer mark unit in this direction to feed back to the exposure machine. For example, please refer to the illustration in FIG. 9, the gap value P and the gap value p may be used to calculate the alignment deviation value in the X direction between the adjacent current layer mark unit 114-1C and front layer mark unit 114-1D, but the present disclosure is not limited thereto. The calculation method of the alignment deviation value may be:

Alignment deviation value X1 in the X direction=(gap value P-gap value p)/2

When X1>0, it means that the current layer mark unit is shifted in the direction of +X relative to the front layer mark unit, resulting in an alignment deviation value X1. When X1<0, it means that the current layer mark unit is shifted in the direction of-X relative to the front layer mark unit, resulting in another alignment deviation value X1. When X1=0, it means that the current layer mark unit has no shift in the X direction relative to the front layer mark unit, so the alignment deviation value X1=0.

According to some other examples of the present disclosure, the gap value Q and the gap value q may be used to calculate the alignment deviation value between the adjacent front-layer key and current-layer key, in other words, between the current layer mark unit 114-1B and the front layer mark unit 114-1A in the Y direction, but the present disclosure is not limited thereto. The calculation method of the alignment deviation value may be:

Alignment deviation value Y1 in the Y direction=(gap value Q-gap value q)/2

When Y1>0, it represents that the current layer mark unit is shifted in the direction of +Y relative to the front layer mark unit, resulting in an alignment deviation value Y1. When Y1<0, it represents that the current layer mark unit is shifted in the direction of-Y relative to the front layer mark unit, resulting in another alignment deviation value Y1. When Y1=0, it represents that the current layer mark unit has no shift in the Y direction relative to the front layer mark unit, so the alignment deviation value Y1=0. The calculation of an alignment deviation value X2 (not shown) or an alignment deviation value Y2 (not shown) of other mark units, such as the mark unit 114-1B and the mark unit 114-1C in the X direction or in the Y direction may be deduced according to the principle, so the details are not elaborated again.

FIG. 10 illustrates a schematic cross-sectional view of an electronic device 102 according to a second example of the present disclosure along the line A-A′ in FIG. 1. FIG. 10A illustrates a schematic cross-sectional view of an electronic device 103 according to a third example of the present disclosure along the line A-A′ in FIG. 1. Please refer to FIG. 10 and to FIG. 10A respectively, the electronic device 102 or the electronic device 103 may respectively include a redistribution layer (RDL) structure 140, a plurality of chip units 120, and a protective layer 130. The chip units 120 at least include a first chip unit 121 and a second chip unit 122 which are surrounded by the protective layer 130, but the present disclosure is not limited thereto. The chip units 120, for example including the first chip unit 121 and the second chip unit 122, may be respectively electrically connected to the redistribution structure 140, and respectively have different chip structures.

The redistribution structure 140 may include a plurality of alignment marks 110. The alignment marks 110 at least include a first alignment mark 111, a second alignment mark 112, a third alignment mark 113 and a fourth alignment mark 114, but the present disclosure is not limited thereto. In some examples of the present disclosure, for example from a cross-sectional direction as shown in FIG. 10 or in FIG. 10A, the chip units and the alignment marks may be arranged along a given direction. In other examples of the present disclosure, the first chip unit 121 may be disposed between the first alignment mark 111 and the third alignment mark 113. In addition, the second chip unit 122 may be disposed between the second alignment mark 112 and the fourth alignment mark 114, but the present disclosure is not limited thereto.

According to some examples of the present disclosure, the second alignment mark 112 and the third alignment mark 113 may be disposed adjacent to each other. In the present disclosure, alignment marks which are arranged adjacent to each other may refer to an embodiment in which no other alignment mark is arranged between the indicated alignment marks. In other examples of the present disclosure, the second alignment mark 112 and the third alignment mark 113 together may be disposed between the first chip unit 121 and the second chip unit 122.

In some embodiments of the present disclosure, the first alignment mark 111, the second alignment mark 112, the third alignment mark 113 and the fourth alignment mark 114 may be an island-like mark, a window-like mark or a hybrid mark respectively. Please refer to the above description for the details of the island-like marks, the window-like marks or the hybrid marks. FIG. 10 shows an example in which the alignment marks 110 may be island-like marks, and FIG. 10A shows an example in which the alignment marks 110 may be window-like marks, but the present disclosure is not limited thereto.

According to some examples of the present disclosure, the number of the alignment marks may be greater than the number of the chip units. FIG. 10 or FIG. 10A shows four alignment marks, such as the first alignment mark 111, the second alignment mark 112, the third alignment mark 113 and the fourth alignment mark 114, which are more than two chip units, such as an example of the first chip unit 121 and the second chip unit 122, but the present disclosure is not limited thereto.

The redistribution structure 140 may be electrically connected to an electronic unit 150 and to a plurality of bumps 160. The bumps 160 may be fabricated by printing, chemical plating or electroplating, but the present disclosure is not limited thereto. According to some embodiments, the redistribution structure 140 may be disposed on at least one side of the electronic unit 150, for example, between the bumps 160 and the electronic unit 150, so as to electrically connect the electronic unit 150 below and the bumps 160 above. FIG. 10 and FIG. 10A respectively show an example in which the redistribution structure 140 is disposed on the upper side of the electronic unit 151, or between the bumps 160 and the electronic unit 152, so as to respectively electrically connect the electronic unit 151 and the electronic unit 152 below and the bumps 160 above, but the present disclosure is not limited thereto. The redistribution structure 140 may include a conductive layer 141 of a single-layer structure or of a stacked-layer structure, and an insulating layer 142 of a single-layer structure or of a stacked-layer structure. The conductive layer 141 includes, for example, a conductive layer 141A, a conductive layer 141B, or further includes a conductive layer 141C (shown in FIG. 10B) to serve as a seed layer, and the insulating layer 142 such as an insulating layer 142A and an insulating layer 142B, so that the conductive layer 141 and the insulating layer 142 in the redistribution structure 140 are stacked alternately along the Z direction to form the redistribution structure 140 of single-layer or multi-layer composite layer, and may further include a thin film transistor (TFT) to form a composite layer structure. The thin film transistor (not shown) may include components such as a gate (not shown), a source (not shown), a drain (not shown) and a semiconductor material (not shown), but the present disclosure is not limited thereto. The electronic device 102 or the electronic device 103 which includes the redistribution structure 140 may facilitate the circuit redistribution of the electronic device 102 or the electronic device 103, or increase the fan-out range of the circuits of the electronic unit 150, to increase the number of signal contacts.

In some embodiments, each one of the bumps 160 may independently include a conductive material. The conductive material may include, for example, a solder material, a bonding material, anisotropic conductive film (ACF) glue, a metal pillar, an alloy, other suitable materials, or a combination of the above conductive materials for use in packaging, but the present disclosure is not limited thereto. The metal may include, for example, copper, silver, titanium, nickel, gold, tin or a combination of the above, and the alloy may include a copper alloy, a silver alloy or a tin alloy, but the present disclosure is not limited thereto. In some embodiments, each one of the bumps 160 may independently include a solder, a bonding pad, anisotropic conductive film glue, or a copper pillar, but the present disclosure is not limited thereto.

The conductive layer of the redistribution structure 140 may include a metal, an alloy, other suitable materials, or a combination of the above conductive materials for use in packaging, but the present disclosure is not limited thereto. The metal may include copper, nickel, gold, titanium, molybdenum, aluminum or other suitable materials, and the alloy may include an alloy of the aforementioned metals, but the present disclosure is not limited thereto. The insulating layer of the redistribution structure 140 may include an organic dielectric material, an inorganic dielectric material, or a combination of the above dielectric materials for use in packaging, but the present disclosure is not limited thereto. The organic dielectric material may include, for example, an ABF substrate, a transparent photoresist, polyimide (PI), such as photosensitive polyimide, other suitable materials, or a combination of the above organic dielectric materials for use in packaging, but the present disclosure is not limited thereto. The inorganic dielectric material may include, for example, silicon oxide, silicon nitride, aluminum oxide, other suitable materials, or a combination of the above inorganic dielectric materials for use in packaging, but the present disclosure is not limited thereto. The Z direction in FIG. 10 and in FIG. 10A is the alternate stacking direction of the conductive layer 141 and the insulating layer 142 of the redistribution structure 140, or may also be regarded as the normal direction of a film layer (such as the surface 100S of the protective layer 130) of the electronic device 102 or the electronic device 103. The X direction and the Y direction together are parallel to the stacking surface of the redistribution structure 140 of the semiconductor device 100, and the X direction is perpendicular to the Y direction. For example, the X direction and the Y direction from FIG. 1 to FIG. 8 are respectively perpendicular to the Z direction shown in FIG. 3. The redistribution structure 140 may be, for example, formed by a deposition process, a patterning process, or other suitable processes. The patterning process may include a laser process, suitable lithography and/or etching processes. The lithography process may include photoresist coating (for example, spin coating), soft bake, mask alignment, exposure, post-exposure bake, photoresist development, rinsing, drying (for example, spin dry and/or hard bake), other suitable lithography techniques, or a combination of the above, but it is not limited thereto. The etching process may include a dry etching (for example, RIE etching), a wet etching, other etching methods, or a combination of the above, but it is not limited thereto. The deposition processes may include a physical vapor deposition (PVD), a chemical vapor deposition (CVD), an atomic layer deposition (ALD), electroplating, chemical plating, electroless plating, a thin film process, other suitable processes, or a combination of the above, but it is not limited thereto.

The electronic unit 151 or the electronic unit 152 may include a plurality of dies, such as the first chip unit 121, the second chip unit 122, a conductive structure 153, and an insulating layer 154. In some examples, the electronic unit 150 including at least the electronic unit 151 or the electronic unit 152 may include known good dies, integrated circuits (ICs), packaged memories, diodes, capacitors, resistors, inductors, and other suitable electronic components, or a combination of the above, but the present disclosure is not limited thereto. The chip units 120 may be disposed in the protective layer 130, for example, the protective layer 130 may be provided to surround the first chip unit 121 and the second chip unit 122. For example, “surround” may refer to an arrangement in which a given element may contact at least two sides of a reference element from a cross-sectional view. FIG. 10 or FIG. 10A shows an arrangement to surround that the protective layer 130 at least contacts two side surfaces of the chip unit, but the present disclosure is not limited thereto. The protective layer 130 may include a solid epoxy molding compound (EMC) for use in packaging structure to be beneficial to reduce the influence of external moisture or oxygen on the electronic unit 150.

FIG. 10B illustrates a schematic partial enlarged view of a partial region 159 of the electronic device 103 in FIG. 10A, showing a profile of structural gap between the protective layer 130 and the insulating layer 154 in the partial region 159. Because the upper surface of the protective layer 130 may be lower than the upper surface of the insulating layer 154, it is beneficial to form a structural gap between the adjacent protective layer 130 and insulating layer 154, and the wiring has a step profile. Such structural features may form an anchoring effect to be conducive to improve the joint strength between different film layers, but it is not limited thereto.

FIG. 10 or FIG. 10A of the present disclosure also provides a packaging structure 100. The packaging structure 100 may include an electronic device, such as the electronic device 102 in FIG. 10 or the electronic device 103 in FIG. 10A, and the bumps 160 for use in the packaging structure 110. According to some examples of the present disclosure, the bumps 160 are disposed on one side of the redistribution structure 140 and electrically connected to the redistribution structure 140. FIG. 10 or FIG. 10A shows an example in which the protective layer 130 may directly contact the first alignment mark 111, the second alignment mark 112, the third alignment mark 113 and the fourth alignment mark 114, but the present disclosure is not limited thereto. According to other examples of the present disclosure, the first alignment mark 111 and the third alignment mark 113 in the packaging structure 100 are provided to correspond to the first chip unit 121, and the second alignment mark 112 and the fourth alignment mark 114 in the packaging structure 110 are provided to correspond to the second chip unit 122. The packaging structure 100 may include a chip-first packaging method, but the present disclosure is not limited thereto.

The electronic unit 151 and the electronic unit 152 may respectively include a conductive structure 153 and an insulating layer 154. For example, the conductive structure 153 and the insulating layer 154 may be respectively disposed on an active surface of the first chip unit 121 or the second chip unit 122. The conductive structure 153 and the insulating layer 154 are disposed between the first chip unit 121 or the second chip unit 122 and the redistribution structure 140, and the conductive structure 153 and the insulating layer 154 may be stacked alternately to form a composite layer structure of a single-layer stack or a multi-layer stack. The insulating layer 154 may be disposed between the redistribution structure 140, the first chip unit 121 or the second chip unit 122 and the conductive structure 153. The conductive structure 153 may be electrically connected to the bonding pad 155 of the first chip unit 121 or of the second chip unit 122, so that the bumps 160 may be electrically connected to the bonding pad 155 of the first chip unit 121 or of the second chip unit 122 via the conductive layer 141 of the redistribution structure 140 and the conductive structure 153. The bonding pad 155 may be an input/output (I/O) terminal of the first chip unit 121 or of the second chip unit 122, but the present disclosure is not limited thereto. The conductive structure 153 may include a conductive material such as a metal, an alloy, other suitable materials, or a combination of the above for use in packaging, but the present disclosure is not limited thereto. The metal may include copper, nickel, gold, titanium, molybdenum, aluminum or other suitable metals, and the alloy may include an alloy of the aforementioned metals, but the present disclosure is not limited thereto. The insulating layer 154 may include an organic dielectric material, an inorganic dielectric material, or a combination of the above dielectric materials for use in packaging, but the present disclosure is not limited thereto. The organic dielectric material may include, for example, an ABF carrier, polyimide, other suitable materials, or a combination of the above organic dielectric materials for use in packaging, but the present disclosure is not limited thereto. The inorganic dielectric material may include, for example, silicon oxide, silicon nitride, aluminum oxide, other suitable materials, or a combination of the above inorganic dielectric materials for use in packaging, but the present disclosure is not limited thereto. For example, in some embodiments, the process steps of the conductive structure 153 may be the same as the process steps of the conductive layer 141 of the redistribution structure 140, or they may be fabricated separately.

In some embodiments of the present disclosure, the process steps of the mark units of the alignment mark may be integrated with the process steps of the conductive layer 141 and the insulating layer 142 of the redistribution structure 140, so that the alignment marks 110 and the redistribution structure 140 may include the same film layer, or the alignment marks 120 are disposed in the redistribution structure 140 and in direct contact with the protective layer 130. In some embodiments of the present disclosure, the mark units in the island-like mark, in the window-like mark or in the hybrid mark may include a combination of a metal layer and an insulating layer. According to some examples of the present disclosure, the number of the metal layer of at least one of the alignment marks may be the same as the number of the metal layer of the redistribution structure. According to some other examples of the present disclosure, the number of the insulating layer of at least one of the alignment marks may be the same as the number of the insulating layer of the redistribution structure. In this way, the process steps of the conductive layer 141 and the insulating layer 142 of the redistribution structure 140 may be integrated with the process steps of each mark unit in the alignment marks, to achieve the beneficial efficacy of less manufacturing steps of the alignment marks. According to some examples, from a top view direction, the opening of the insulating layer 142 to form the alignment marks or the patterned conductive layer 141 may have a rounded corner because the process steps of the mark units of an alignment mark may be integrated with the process steps of the conductive layer 141 and the insulating layer 142 of the redistribution structure 140, but the present disclosure is not limited thereto.

In the packaging structure or in the electronic device of the present disclosure, further, there may be a through-hole structure to be arranged in some examples. The through-hole structure may include a conductive material, and the arrangement of the through-hole structure is beneficial to some functions, such as the heat dissipation function, the positioning function, or the connection with external components or the formation of electrical connections, of the packaging structure or the electronic device of the present disclosure. The packaging structure or the electronic device including the through-hole structure is described as follows.

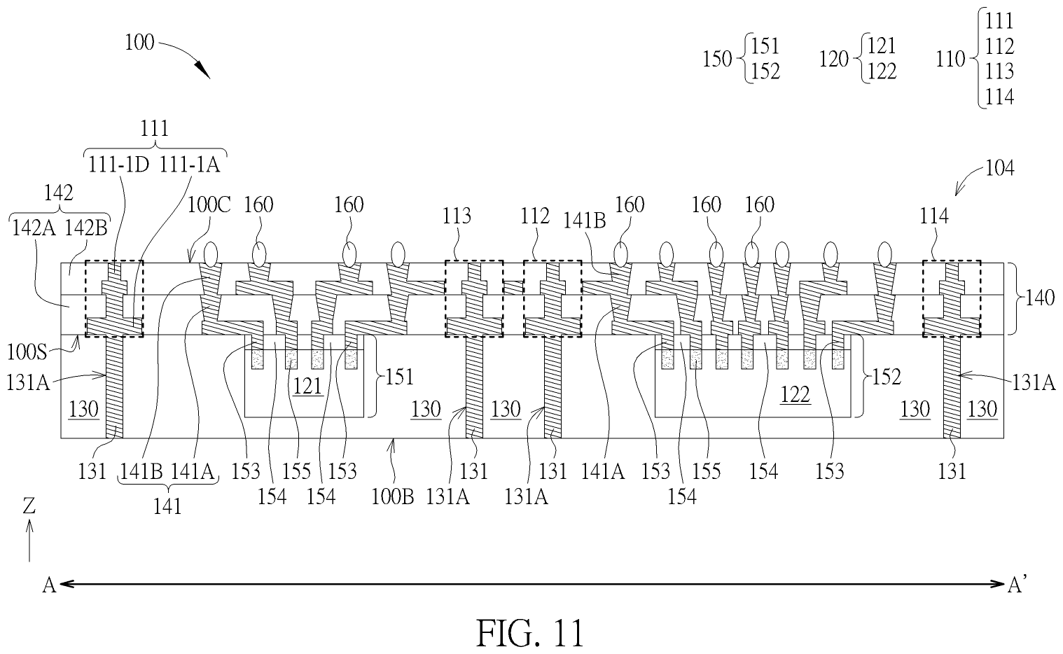

FIG. 11 illustrates a schematic cross-sectional view of an electronic device 104 according to a fourth example of the present disclosure along the line A-A′ in FIG. 1. Please refer to FIG. 11, according to some examples of the present disclosure, the protective layer 130 may have at least one through-hole structure 131. In other words, the through-hole 131A may be formed in the protective layer 130 for accommodating the through-hole structure 131. If the alignment mark is an example of an island-like mark, the through-hole structure 131 may extend from the metal layer of the alignment mark to the protective layer 130, for example, taking the first alignment mark 111 as an example, it may extend from the bottommost mark unit 111-1A in direct contact with the protective layer 130 to the protective layer 130 and exposes a portion of the through-hole structure 131 on the bottom surface 100B opposite to the surface 100C. On the other hand, the topmost mark unit 111-1D of the first alignment mark 111 may also be a metal layer, and a portion of the mark unit 111-1D is exposed on the surface 100C, so that at least one through-hole structure 131 may be electrically connected to a ground signal, or may also be electrically connected to the surface 100C and to the bottom surface 100B of the electronic device 104 via the mark unit 111-1D to become an input/output (I/O) terminal of the bottom surface 100B. Therefore, the through-hole structure 131 may be used for a ground signal or have a heat dissipation function.

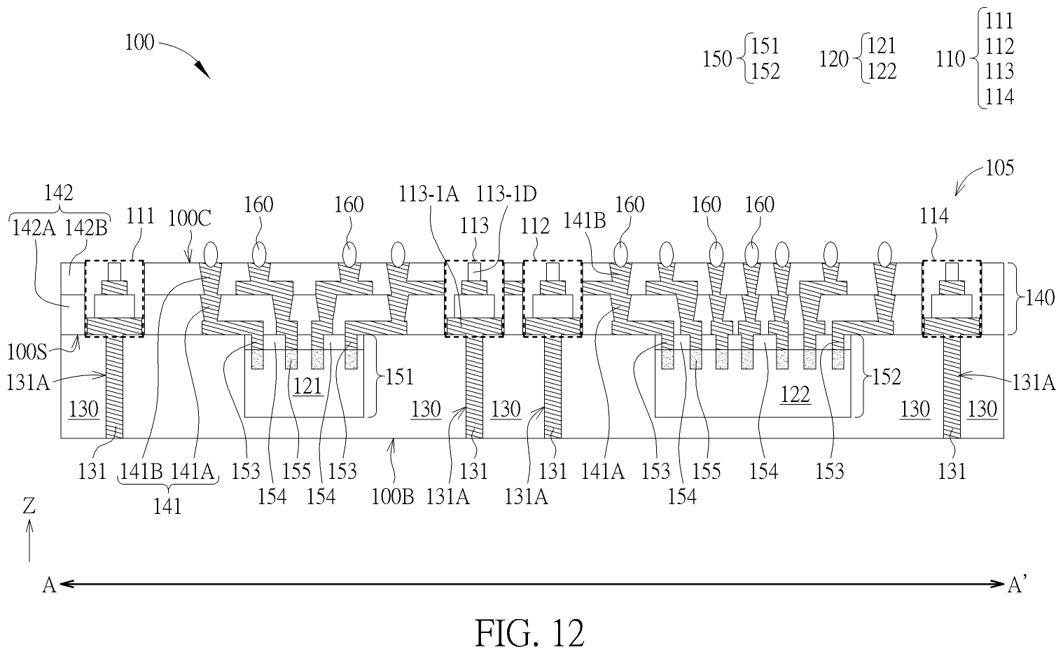

FIG. 12 is a schematic cross-sectional view of an electronic device 105 according to a fifth example of the present disclosure along the line A-A′ in FIG. 1. Please refer to FIG. 12, according to some examples of the present disclosure, the protective layer 130 may have at least one through-hole structure 131. In other words, a through-hole 131A may be formed in the protective layer 130 for accommodating the through-hole structure 131. If the alignment mark is an example of an island-like mark, the through-hole structure 131 may extend from the metal layer of the alignment mark to the protective layer 130. For example, taking the second alignment mark 112 as an example, the through-hole structure 131 may extend from the bottommost mark unit 112-1A in direct contact with the protective layer 130 to the protective layer 130, and a portion of the through-hole structure 131 is expose on the bottom surface 100B opposite to the surface 100S to form a T-shaped cross-sectional structure.

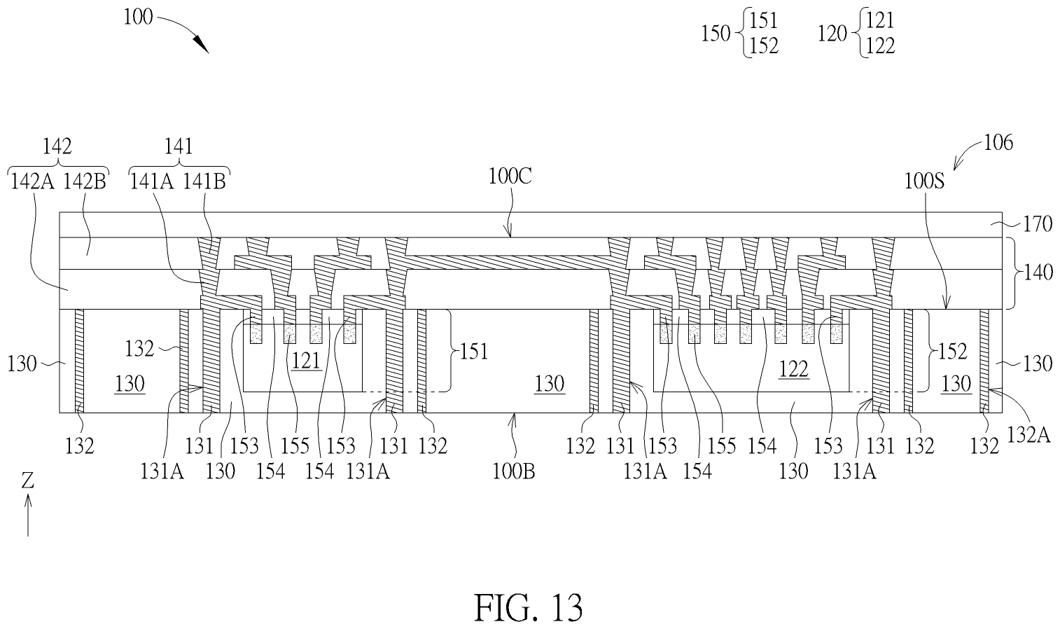

FIG. 13 illustrates a variant embodiment of the electronic device 106 according to a sixth embodiment of the present disclosure corresponding to FIG. 12. Please refer to FIG. 13, according to some embodiments of the present disclosure, the electronic device 106 may have a passivation 170, at least one through-hole structure 131 disposed in the protective layer 130, and at least one ground structure 132, but the redistribution structure 140 may omit the alignment mark. The passivation 170 may be a protective material with insulating properties, to cover the uppermost conductive layer 141B of the conductive layer 141 in the redistribution structure 140, to be conducive to reduce the influence of external moisture or oxygen on the conductive layer 141. For the materials of the passivation 170, please refer to the above description of the insulating layer 142. The conductive material in the through-hole structure 131 may be electrically connected to the conductive layer 141 in the redistribution structure 140 to be beneficial for the connection with external components (not shown). For example, because the passivation 170 covers the surface 100C and the conductive layer 141B, the input and output (I/O) terminals or other electrical connection signals may use the through-hole structure 131 which is electrically connected to the conductive layer 141 to go outward to form electrical connection via the bottom surface 100B. The external components may be printed circuit boards (PCBs) or other suitable components, but the present disclosure is not limited thereto. The ground structure 132 may be disposed in the through-hole 132A or adjacent to the through-hole structure 131, and is designed to be floating to be beneficial for the electronic device 106 to be grounded properly.

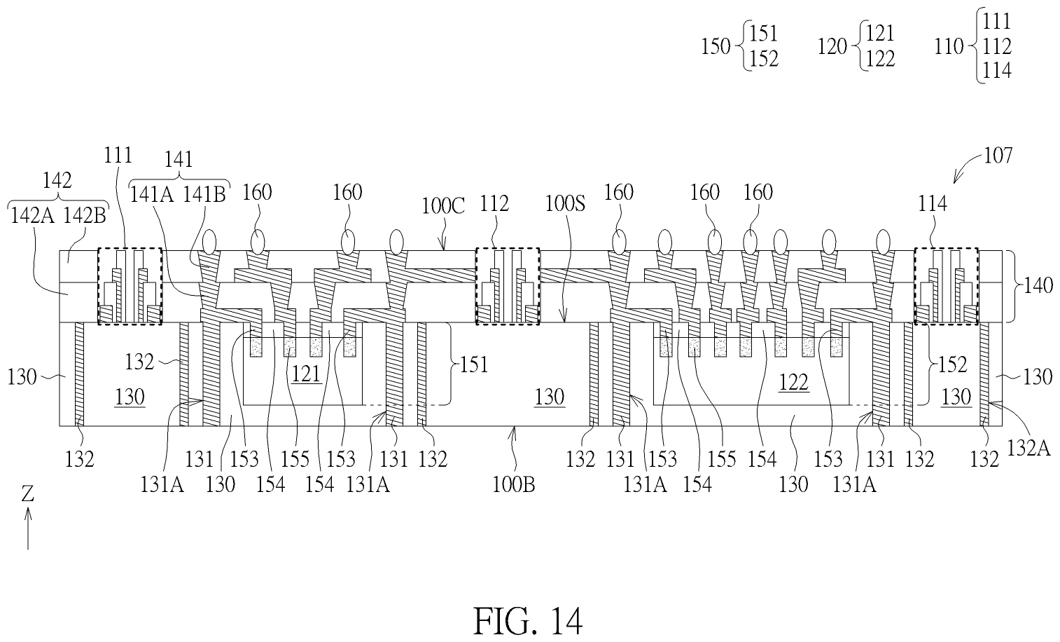

FIG. 14 illustrates a schematic cross-sectional view of an electronic device 107 according to a seventh embodiment of the present disclosure along the line A-A′ in FIG. 1. Please refer to FIG. 14, according to some embodiments of the present disclosure, the electronic device 107 may have at least one through-hole structure 131 in the protective layer 130 and at least one ground structure 132. The alignment marks may be disposed adjacent to the chip units and provided to correspond to the chip units, or disposed between the adjacent chip units. FIG. 14 shows three alignment marks, such as the first alignment mark 111 adjacent to the first chip unit 121, the fourth alignment mark 114 adjacent to the second chip unit 122, and the second alignment mark 112 disposed between the adjacent first chip unit 121 and second chip unit 122. The conductive material in the through-hole structure 131 may be electrically connected to the conductive layer 141 in the redistribution structure 140 to be beneficial for the connection with external components (not shown). The ground structure 132 may be disposed adjacent to the through-hole structure 131 and designed to be floating to be beneficial for the electronic device 107 to be grounded properly.

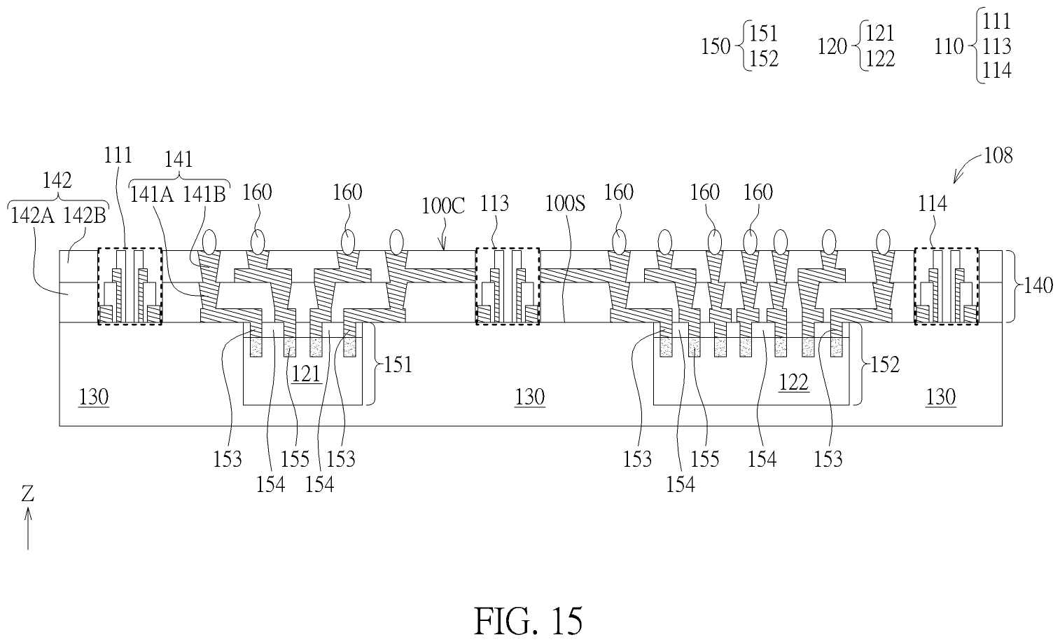

FIG. 15 illustrates a schematic cross-sectional view of an electronic device 108 according to an eighth example of the present disclosure along the line A-A′ in FIG. 1. Please refer to FIG. 15, according to some embodiments of the present disclosure, the electronic device 108 may have three alignment marks, such as the first alignment mark 111 adjacent to the first chip unit 121, the fourth alignment mark 114 adjacent to the second chip unit 122, and the third alignment mark 113 disposed between the adjacent first chip unit 121 and second chip unit 122.

The present disclosure proposes an alignment mark, so that the position occupied by the alignment mark in an electronic device with multiple chip units may not increase due to the development of multi-stacking layers, which is beneficial to the flexibility of the circuit design in the electronic device. On the other hand, an alignment mark including a test key is proposed to have the function of measuring the alignment deviation value, so that the alignment mark may become a versatile mark to reduce the need to occupy the layout space to save the space in the packaging structure or in the electronic device, and to improve the alignment accuracy between components or increase the space utilization rate in the electronic device. The electronic devices of the present disclosure may include at least three layers which stack in one of the alignment marks. This kind of stacking alignment marks may use 3D X-ray to determine the stacked pattern and the alignment marks.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a redistribution structure comprising a plurality of alignment marks;
a plurality of chip units electrically connected to the redistribution structure and comprising a first chip unit and a second chip unit; and
a protective layer surrounding the first chip unit and the second chip unit,
wherein the plurality of chip units and the plurality of alignment marks are arranged along a first direction in a cross-sectional view direction, the plurality of alignment marks comprise a first alignment mark, a second alignment mark, a third alignment mark and a fourth alignment mark, the first chip unit is disposed between the first alignment mark and the third alignment mark, the second chip unit is disposed between the second alignment mark and the fourth alignment mark, the second alignment mark and the third alignment mark are disposed between the first chip unit and the second chip unit, and a number of the plurality of alignment marks is greater than a number of the plurality of chip units.

2. The electronic device of claim 1, wherein the plurality of alignment marks and the redistribution structure comprise same film layers.

3. The electronic device of claim 1, wherein a number of metal layers of at least one of the plurality of alignment marks is the same as a number of metal layers of the redistribution structure.

4. The electronic device of claim 1, wherein a number of insulating layers of at least one of the plurality of alignment marks is the same as a number of insulating layers of the redistribution structure.

5. The electronic device of claim 1, wherein at least one of the plurality of alignment marks comprise a test key for use in measuring an alignment deviation value.

6. The electronic device of claim 5, wherein the test key comprises a front-layer key and a current-layer key, there are a first gap value Q and a second gap value q between the front-layer key and the current-layer key along a second direction, and the first direction is perpendicular to the second direction.

7. The electronic device of claim 6, wherein the alignment deviation value is defined as (Q−q)/2 which is determined by the first gap value Q and the second gap value q between the front-layer key and the current-layer key.

8. The electronic device of claim 1, wherein an extension line of the first alignment mark and an extension line of the second alignment mark have an included angle, and the included angle is greater than or equal to 0 degree and less than or equal to 15 degrees.

9. The electronic device of claim 1, wherein at least one of the plurality of alignment marks comprises a rounded corner.

10. The electronic device of claim 1, wherein the protective layer has at least one through-hole structure, and the at least one through-hole structure is electrically connected to a ground signal.

11. The electronic device of claim 10, wherein the at least one through-hole structure is an input/output terminal (I/O).

12. The electronic device of claim 10, wherein the through-hole structure is used to dissipate heat.

13. The electronic device of claim 10, further comprising:
a ground structure adjacent to the at least one through-hole structure.

14. The electronic device of claim 10, wherein the at least one through-hole structure is electrically connected to a conductive layer in the redistribution structure.

15. The electronic device of claim 1, comprising at least three layers which stack in one of the plurality of the alignment marks.

16. The electronic device of claim 1, wherein at least one of the plurality of alignment marks is in direct contact with the protective layer.

17. The electronic device of claim 1, wherein at least one of the plurality of alignment marks comprises one of an island-like mark, a window-like mark and a hybrid mark.

18. The electronic device of claim 1, wherein at least one of the plurality of alignment marks comprises a plurality of mark units.

19. The electronic device of claim 18, wherein the plurality of mark units are correspondingly stacked to form a tower-like alignment mark.

20. The electronic device of claim 18, wherein there are n pieces of the plurality of mark units to form one of the plurality of alignment marks with n/2 layers when n is an even number.
